(19) United States
(12) Patent Application Publication
(10) Pub. No.: US 2012/0015459 A1
(43) Pub. Date: Jan. 19, 2012

(54) Thermal Leveling for Semiconductor Devices

(75) Inventors: Chun Hsiung Tsai, Xinpu Township (TW); Han-Pin Chung, Fongshan City (TW); Ming-Hsi Yeh, Hsin-Chu (TW); De-Wei Yu, Ping-tung (TW); Kuan-Yu Chen, Taipei City (TW)

(73) Assignee: Taiwan Semiconductor Manufacturing Company, Ltd., Hsin-Chu (TW)

(21) Appl. No.: 12/837,114

(22) Filed: Jul. 15, 2010

(51) Int. Cl. H01L 21/66; H01L 21/30; H01L 21/26

(52) U.S. Cl. 438/16; 438/795; 438/758; 257/E21.328; 257/E21.211; 257/E21.53

(57) ABSTRACT

A semiconductor device and a method of manufacturing are provided. In some embodiments, a backside annealing process such that a first heat source is placed along a backside of the substrate. In other embodiments, the first heat source is used in combination with an anti-reflection dielectric (ARD) layer is deposited over the substrate. In yet other embodiments, a second heat source is placed along a front side of the substrate in addition to the first heat source placed on the backside of the substrate. In yet other embodiments, a heat shield may be placed between the substrate and the second heat source on the front side of the substrate. In yet further embodiments, a single heat source may be used on the front side of the substrate in combination with the ARD layer. A reflectivity scan may be performed to determine which anneal stage (RTA or MSA or both) to place thermal leveling solution.

### TECHNICAL FIELD

The present disclosure relates generally to semiconductor devices and, more particularly, to thermal leveling techniques for forming semiconductor devices.

### BACKGROUND

In general, semiconductor devices are fabricated by depositing and patterning one or more conductive, insulating, and semiconductor layers to form specific devices, such as transistors, resistors, capacitors, and the like, which together form integrated circuits. In one technique, a thin layer of semiconductor material is doped to alter the electrical characteristics of the material. Generally, doping is the process of implanting ions into the semiconductor material and may be performed by an ion implant process wherein the semiconductor layer is bombarded with N-type and/or P-type ions or by an in situ process wherein ions are introduced as the semiconductor layer is being formed.

After the doping process, an annealing process is typically performed to activate the implanted N-type and/or P-type ions. When performing the annealing procedure, however, it has been found that the individual dies of a wafer may not heat evenly. Rather, the die may exhibit a significant amount of temperature variation across the die. One type of temperature variation is referred to as a systematic variation and results in temperature variation bands such as a pattern of concentric rings extending outward from a center. Another type of temperature variation is referred to as a random variation, which has no discernable pattern.

This temperature variation across the die may result in the various electrical devices, e.g., transistors, resistors, capacitors, and the like, to exhibit different electrical characteristics. For example, when a first region, e.g., edges of a die, may be heated to a significantly lower temperature than a second region, e.g., the center of the die, the dopants in the second region may not be sufficiently activated resulting in increased resistance and greater circuit delays as compared to the first region. As a result, the various portions of the integrated circuit may have different electrical characteristics based simply upon the position of the various portions on the die.

### SUMMARY

These and other problems are generally reduced, solved or circumvented, and technical advantages are generally achieved, by embodiments of the present disclosure, which provides temperature-leveling techniques to reduce temperature variations across a die.

In an embodiment, a reflectivity scan is performed over a die to determine a reflectivity variation, which is characterized as a systematic variation or a random variation. The random variation may be further characterized by the relative scales of the variations. Based upon a type and/or scale of variation, a solution for reflectivity induced variation is determined for RTA or MSA anneal process.

In an embodiment, a backside heat source is utilized. In other embodiments, a front side heat source is utilized with an anti-reflection deposition (ARD) layer. In yet other embodiments, a backside heat source is utilized with or without a heat absorption layer. In still yet other embodiments, a front side and a backside heat source is utilized in combination with an ARD layer. In still yet other embodiments, a front side and a backside heat source is utilized in combination with an ARD layer and a heat shield.

Other embodiments are disclosed.

### BRIEF DESCRIPTION OF THE DRAWINGS

For a more complete understanding of the present disclosure, and the advantages thereof, reference is now made to the following descriptions taken in conjunction with the accompanying drawing, in which:

FIG. 1 is a process flow diagram for determining a type of reflectivity variation on a die in accordance with an embodiment;

FIG. 2 illustrates a reflectivity scan on a die exhibiting a systematic variation;

FIG. 3 illustrates a reflectivity scan exhibiting a random variation;

FIG. 4 illustrates a backside anneal process in accordance with an embodiment;

FIG. 5 illustrates a front side anneal process on a die having an anti-reflection (ARD) layer;

FIG. 6 illustrates a backside anneal process in combination with an ARD layer;

FIG. 7 illustrates a dual-side anneal process in combination with an ARD layer; and

FIG. 8 illustrates a dual-side anneal process in combination with an ARD layer and a heat shield.

### DETAILED DESCRIPTION

The making and using of the illustrative embodiments are discussed in detail below. It should be appreciated, however, that the present disclosure provides many applicable inventive concepts that can be embodied in a wide variety of specific contexts. The specific embodiments discussed are merely illustrative of specific ways to make and use various embodiments, and do not limit the scope of the disclosure.

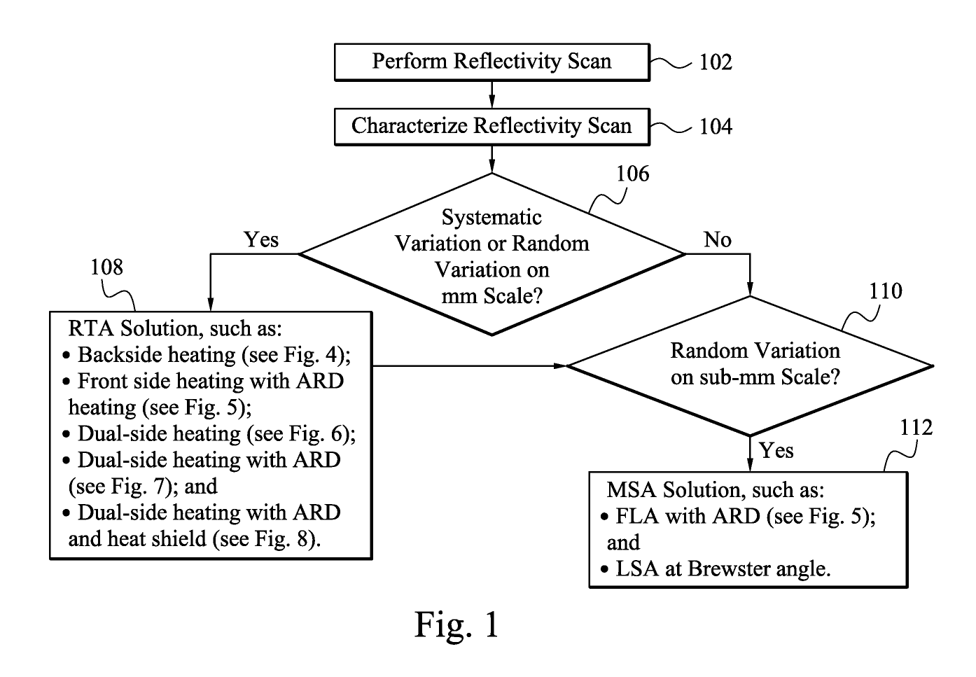

FIG. 1 is a process flow diagram that illustrates the basic steps in accordance with an embodiment. Additional detail regarding the individual steps will be provided below. The process begins in step 102, wherein a reflectivity scan of an integrated circuit die is performed. It has been found that the reflectivity variation over the integrated circuit die is a significant contributor to the temperature variations. The reflectivity of the integrated circuit die is a factor of the materials used and the density of the devices, e.g., transistors, resistors, capacitors, or the like. In general, it has been found that areas exhibiting a higher reflectivity results in cooler temperatures as opposed to areas exhibiting lower reflectivity. The higher the reflectivity, the greater the amount of the radiation energy of the heat source will be reflected during the anneal process.

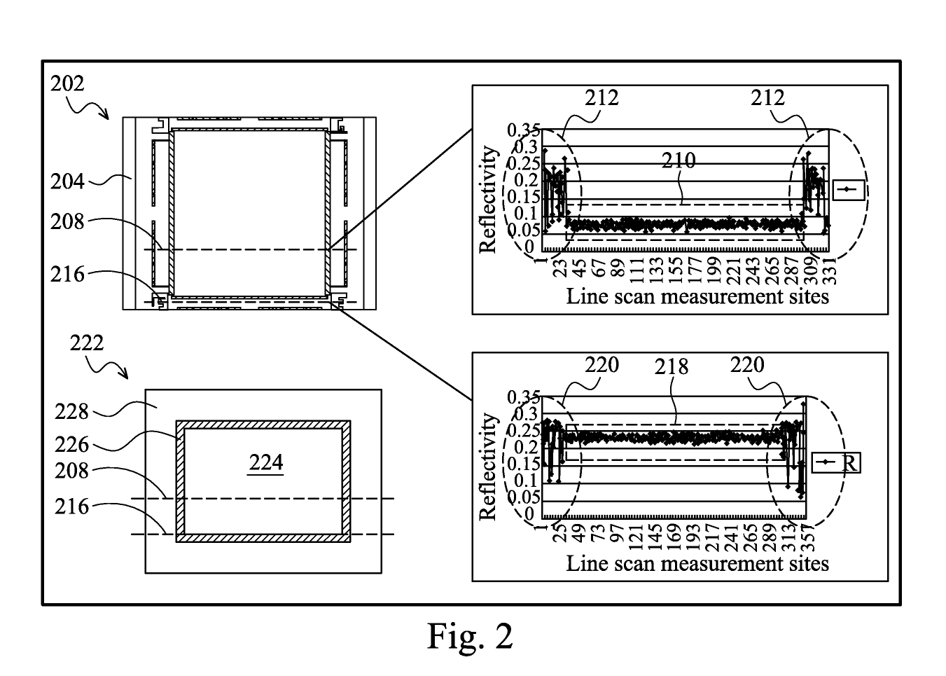

In an embodiment, the reflectivity scan is performed utilizing a Xeon light source. A Xeon light source is a broad band light source having a wavelength from about 250 nm to about 750 nm. By utilizing a spot size of about 2.9 μm to about 50 μm and a stepping distance between measurement points of about 20 μm to about 100 μm, a one or two dimensional reflectivity map with high spatial resolution may be obtained. In the example provided above, a step size of about 20 μm results in a reflectivity map having an accuracy of about 20 μm. An example of a reflectivity scan is provided below with reference to FIG. 2.

While other types of scans and different sources may be used, it may be desirable to use a light source having a relatively short wavelength. Generally, the shorter wavelengths have greater reflectivity sensitivity and provide greater accuracy based on the density of the devices on the integrated circuit die. Thus, other light sources having shorter or longer wavelengths may be used to best suit the specific application.

Thereafter, in step 104, the results of the reflectivity scan is characterized. As explained below, the method or technique used to anneal the wafer depends upon the type of variation exhibited by the die. In an embodiment, the reflectivity scan, which is an indication of the temperature variations exhibited by a die, is characterized as a systematic variation or a random variation. A systematic variation is one in which the reflectivity scan illustrates a pattern, e.g., concentric rings, whereas a random variation has no specific pattern. Examples of a random variation include bands spanning across the die or random regions of differing reflectivity.

In step 106, a determination is made whether the variation is systematic or random variation on a mm scale. Based upon the type of variation, the ODV solution to implement at RTA or MSA will be determined. Generally, the systematic variation typically exhibits spatial variations greater than a mm scale, whereas a random variation may exhibit spatial variations on a mm or smaller scale (e.g., μm scale). It has been found that when the on-die variation is systematic or random on a mm scale, an ODV solution implemented at RTA process is effective. On the other hand, for random variation on a sub-mm scale, e.g., a μm scale, an ODV solution implemented at MSA process is more effective in reducing the on-die variations. Thus, if the variation is systematic or a larger random variation, e.g., on a mm scale, then processing proceeds to step 108, wherein an ODV solution at RTA stage is implemented, such as backside heating, dual-side heating, a heat shield and/or an anti-reflection deposition (ARD) RTA process. Thereafter, and in the case that in step 106 it is determined that no systematic variation exists and any random variation is not on a mm-scale, then processing proceeds to step 110, wherein a determination is made whether the die exhibits regions of random variation is on a sub-mm scale (e.g., μm scale) or a smaller scale. If in step 110 a determination is made that the random variation is on a sub-mm scale, then processing proceeds to step 112, wherein an ODV solution for millisecond anneal (MSA) is implemented, e.g., a laser spike anneal (LSA), a flash lamp anneal (FLA) with ARD layer, or the like, is used.

FIG. 2 illustrates a reflectivity scan in accordance with an embodiment. A density map 202 illustrates the density of the active areas of an integrated circuit die 204 having dimensions of about 2 cm by about 2 cm. Active areas generally comprise a doped region of the substrate. These denser regions will typically exhibit a higher reflectivity. For example, a center-line reflectivity plot 206 and a bottom-line reflectivity plot 214 illustrate plots that were obtained using a spot size of about 3 μm with a spot-to-spot separation of about 20 μm with a light source wavelength of about 250 μm to about 750 μm.

The center-line reflectivity plot 206 indicates the reflectivity measured along a center scan line 208 and indicates that a center region 210 has a lower reflectivity than side regions 212. Generally, the lower the reflectivity, the hotter the region will become during a typical front-side RTA. The center-line reflectivity plot 206 also indicates that the center region 210 is consistent and that there is no random variation.

The bottom-line reflectivity plot 214 indicates the reflectivity measured along a bottom scan line 216 and indicates that along the bottom scan line 216 a center region 218 has a higher reflectivity than side regions 220. As a result, it is expected that the side regions 220 along the bottom scan line 216 may have a higher temperature than the center region 218. As illustrated in FIG. 2, the bottom scan line 216 has a row of higher density areas along the center region.

The reflectivity plots (FIG. 2 showing two) may be used to create a heat diffusion model 222. As illustrated in the heat diffusion model 222, a center region 224 has a lower reflectivity and hence a higher temperature. A band region 226 has a higher reflectivity, and thus corresponds to a lower temperature. A border region 228 corresponds to the side regions 220 of the bottom-line reflectivity plot 214, which exhibited a reflectivity about as high as the center region 210 of the center-line reflectivity plot 206. As illustrated by the center-line reflectivity plot 206, the reflectivity variations range from about 0.08 in the center region 210 to about 0.2 in the side regions 212, and the bottom-line reflectivity plot 214 illustrates that the reflectivity variations range from about 0.23 in the center region 218 to about 0.21 in the side regions 220. In an embodiment, when the reflectivity variations are smaller than about some predetermined limit, such as about 0.05, within a spatial distance larger than 1 mm, then the reflectivity variation may be characterized as on a mm scale, and thus, FIG. 2 represents a case of systematic variation. In contrast, for the similar case if the distance is less than 1 mm then the reflectivity variation may be characterized as random variation. The predetermined limit may be a value to account for noise between measurements. In an embodiment, a predetermined value of about 0.05 may be used, such that reflectivity variations of less than about 0.05 are ignored.

It should be noted that the side regions 220 itself includes reflectivity variations greater than 0.05, which may indicate a random variation. However, because the center region exhibits a relatively large area having very little reflectivity variations, the variations illustrated in FIG. 2 is considered systematic. As discussed above, if a die has both systematic variations as well as sub-mm scale random variation, then both a RTA solution and a MSA solution may be used. However, in an embodiment, if the random variations is less than about 10% of the die, then it may be possible to ignore the random variation and only perform a RTA-related solution as described above (see, e.g., step 108 of FIG. 1), because characteristic heat diffusion of mm scale of the longer time period of the RTA solutions is sufficient to also correct the on-die variations due to the smaller regions of random variations.

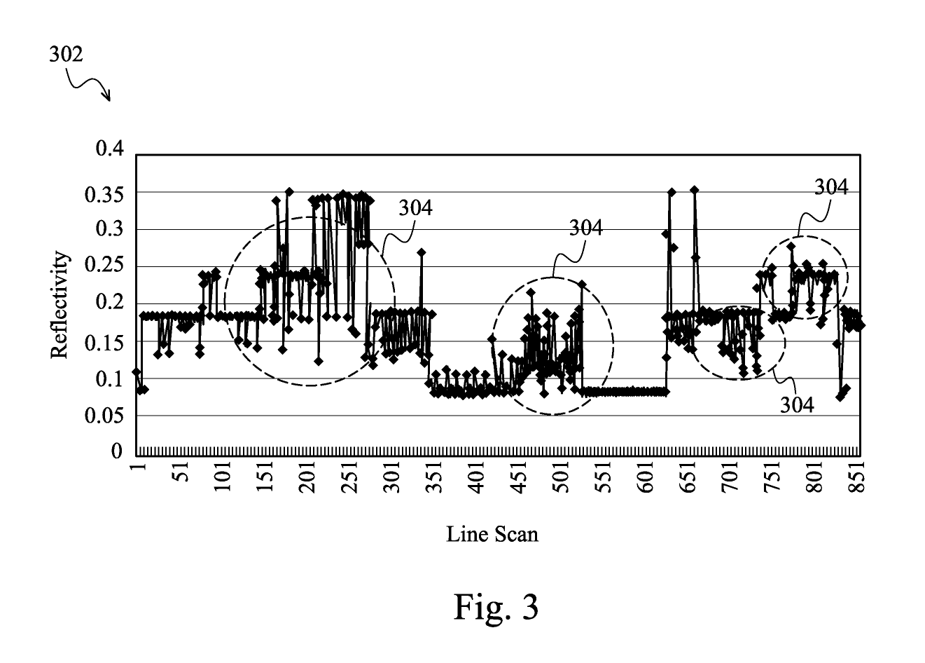

FIG. 3 illustrates a random/systematic reflectivity plot 302 that indicates a hybrid/random variation, as opposed to a systematic variation, in accordance with another embodiment. The die from which the random reflectivity plot 302 was taken from has dimensions of about 1.7 cm by about 2 cm. As can be seen from the random reflectivity plot 302, the reflectivity variations range from less than 0.1 to 0.35. In this case, the reflectivity variance is greater than about 0.05 within a spatial distance of less than mm scale in some local positions, while in some other local positions the reflectivity variance is greater than about 0.05 within a spatial distance of greater than mm scale. FIG. 3 represents a case of hybrid random/systematic variation. For example, FIG. 3 illustrates local positions 304 that include reflectivity variance greater than about 0.05, thereby indicating that the variation is a random variation. It should be noted, however, that FIG. 3 also exhibits local portions having a systematic variation, such as the region extending from about position 351 to about position 451 on the line scan. In this example, a RTA solution and a MSA solution may be performed as discussed above with reference to FIG. 1.

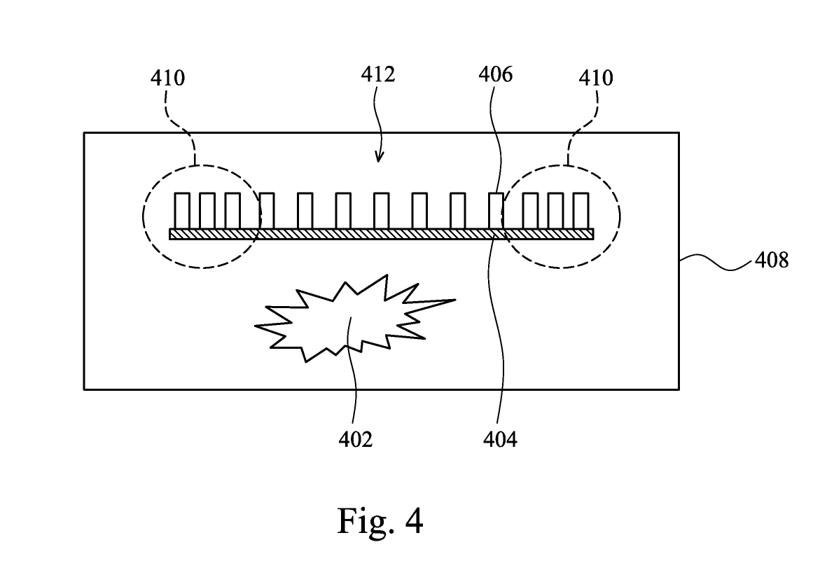

FIGS. 4-8 illustrate various types of annealing that may be utilized to reduce the on-die temperature variation, thereby heating the integrated circuit die and wafer more evenly, wherein like reference numerals refer to like elements. These figures reference a heat source 402, which may vary depending upon the characterization of the on-die variation. In general, for a random variation having a spatial variation on the mm or greater scale or a systematic variation, a RTA related on-die variation (ODV) solution may be desirable, such as backside heating, dual-side (front and back) heating, front side heating with an ARD layer, dual-side heating with an ARD layer, dual-side heating with an ARD layer and a heat shield, or the like. For random variations having a spatial variation on a sub-mm scale, e.g., sub-100 μm scale, a millisecond anneal (MSA) related ODV solution may be desirable, such as a laser spike anneal (LSA) or FLA with an ARD layer.

In general, the thermal diffusion rate using an RTA process is in the mm range. Thus, annealing problems associated with on-die variations in the about 1 mm range may be reduced or prevented using an RTA related process solution, which uses a broad band heat source having a wavelength between about 0.4 μm to about 3 μm. MSA processes, however, generally have a thermal diffusion rate in the about 100 μm range. Thus, MSA related process solutions may reduce or prevent annealing problems associated with on-die variations in the sub-mm range, but may be relatively ineffective in solving annealing problems in the 1 mm range. Accordingly, the heat source 402 in the following descriptions may refer to an RTA, or the like dependent upon the type of on-die variation. In an embodiment, the heat source for the LSA process may have a wavelength of about 10.56 μm, and the heat source for the FLA process may be a broad band source having a wavelength range from about 250 nm to about 750 nm.

Referring now to FIG. 4, a backside anneal process is illustrated for an RTA solution. A substrate 404 having devices 406 formed thereon is shown placed in an annealing chamber 408. The substrate 404 represents a substrate having ions implanted therein. It should be noted that the devices 406 are illustrated as blocks for illustrative purposes only and are used to illustrate the relative density over a substrate. For example, FIG. 4 indicates that the edge regions 410 are denser than a middle region 412 between the edge regions 410. The devices 406 may represent transistors, resistors, capacitors, or the like. It should also be noted that the relative density may vary to reflect a systematic or random variation. Further, substrate 404 is illustrated as a single die, but may represent a wafer having a plurality of dies.

In the embodiment illustrated in FIG. 4, the heat source 402, is placed on the backside of the substrate 404, i.e., on the side of the substrate 404 opposite the devices 406. In this manner the heating is performed through the substrate 404 and any other layers, e.g., silicon nitride layers or the like. The substrate 404 acts to more evenly dissipate the heat to the devices 406. While this method may reduce the temperature variation, local temperature variation may still be present due to the radiator effect as heat is dissipated through the substrate.

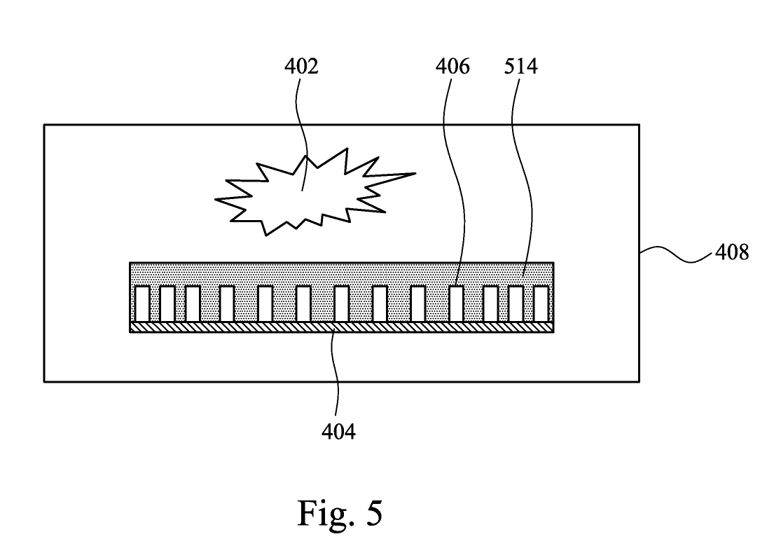

FIG. 5 illustrates an embodiment in which an ARD layer 514 is deposited over the devices 406 prior to the annealing. The ARD layer 514 acts as a heat sink and thermal conduction layer to better dissipate the heat from the heat source 402. The ARD layer 514 also acts to reduce the variation in reflectivity across the surface of the die. As noted above, the variation in the reflectivity across the die results in a variation of temperatures reached by the various sections of the die, wherein areas of low reflectivity absorb more heat and reach higher temperatures, and areas of high reflectivity absorb less heat and remain relatively cooler. As such, the ARD layer 514 may be used to reduce the reflectivity variation such that the different areas of the die reflect the radiation energy by about the same amount, allowing the die to heat more evenly.

In this embodiment, the heat source 402 is positioned on the front side of the substrate 404. In an embodiment, the ARD layer 514 is formed of a dielectric material having a heat absorption coefficient of about 0.1. For example, the ARD layer 514 may be formed of an amorphous carbon material formed by chemical vapor deposition (CVD) techniques using C₂H₂ diluted with He at a temperature of about 350° C. to a thickness of about 4,000 Å. While the optimum thickness may be dependent upon the height of the devices 406 and heat absorption coefficient (k), it is believed that the thickness of the ARD layer 514 should be sufficient for radiation heat absorption such that the device topography and reflectivity induced thermal variation can be reduced or eliminated.

In another embodiment, the ARD layer 514 may be formed of a material having a higher heat absorption coefficient. This embodiment is similar to the embodiment discussed above, except that a material having a higher heat absorption coefficient, e.g., a heat absorption coefficient of about 0.3, is used. For example, a material such as amorphous carbon formed by CVD techniques using C₂H₂ diluted with He at a temperature of about 400° C. to a thickness of about 4,000 Å to have a heat absorption coefficient of about 0.3. It should be appreciated that the heat absorption coefficient of the amorphous carbon layer may be determined at least in part by adjusting the flow rate of the C₂H₂ relative to the flow rate of the He. Generally, the slower the flow rate of the C₂H₂, the higher the heat absorption coefficient. The higher heat absorption coefficient achieves higher heat absorption; ARD thickness and heat absorption coefficient are tuned to ensure radiation heating is completely or near completely absorbed.

The anneal process illustrated in FIG. 5 may be, for example, a RTA for a random variation on the mm scale or a systematic variation, or an LSA or an FLA for a random variation on sub-mm scale. Although it should be noted that because the LSA uses a relatively large wavelength, the ARD layer 514 is not as advantageous as when using an RTA or FLA anneal process that uses a heat source having a relatively shorter wavelength. The longer wavelength of the LSA is susceptible to reflectivity-related issues, and thus the ARD provides less of an advantage.

Thereafter, the ARD layer 514 may be removed and subsequent processing may be performed. The ARD layer 514 may be removed using an O₂/CF₄ ashing process with a subsequent SPM (sulfuric acid-hydrogen peroxide mixture) wet process. Alternatively, the ARD layer 514 may be removed using a high temperature (e.g., greater than 150° C.) SPM wet process.

Subsequent processing may include, for example, forming an inter-layer dielectric (ILD), contacts, inter-metal dielectric (IMD) layers, metallization layers, packaging, and the like.

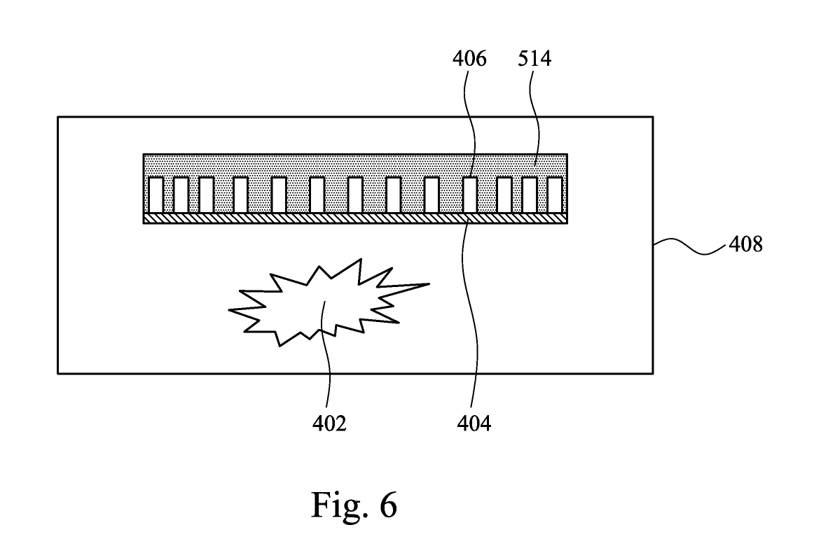

FIG. 6 illustrates another embodiment for an annealing process. This embodiment combines the use of the ARD layer 514 and placement of the heat source 402 on the backside of the substrate 404. This embodiment advantageously combines the effect of heating through the substrate 404 for the reduction of reflectivity induced variation and the ARD layer 514 to act as a heat sink for even heat dissipation, thereby allowing for less temperature variation between the various regions of the die. The anneal process illustrated in FIG. 6 may be, for example, a RTA for a random variation on a mm scale or a systematic variation.

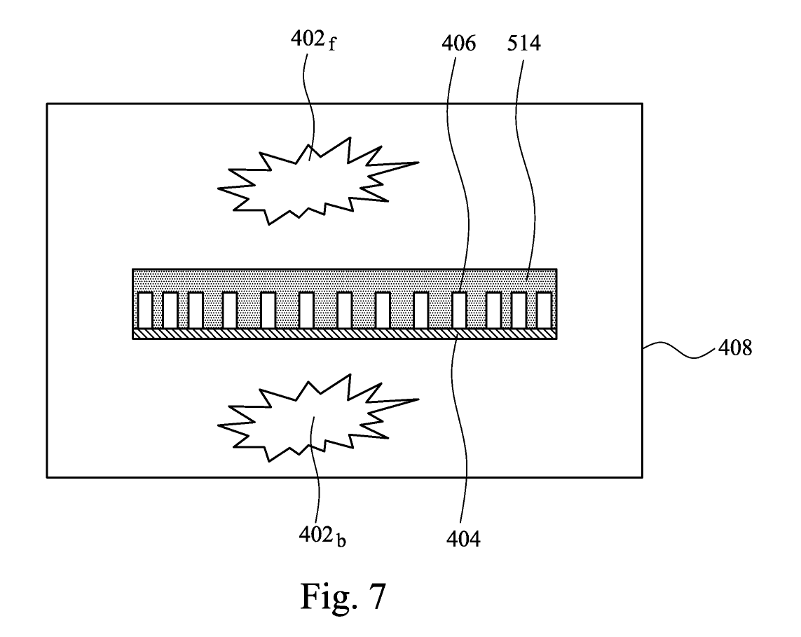

FIG. 7 illustrates yet another embodiment for an annealing process. This embodiment is a combination of those embodiments discussed above with reference to FIGS. 5 and 6, except the heat source 402 in FIGS. 5 and 6 is replaced with a front side heat source 402_{f} and a backside heat source 402_{b}. This embodiment also utilizes the ARD layer 514 as discussed above. The use of the front-side heat source 402_{f} and the back-side heat source 402_{b} allows for more even heating and less temperature variation, particularly when coupled with the ARD layer 514. The anneal process illustrated in FIG. 7 may be, for example, a RTA for a random variation on a mm scale or a systematic variation.

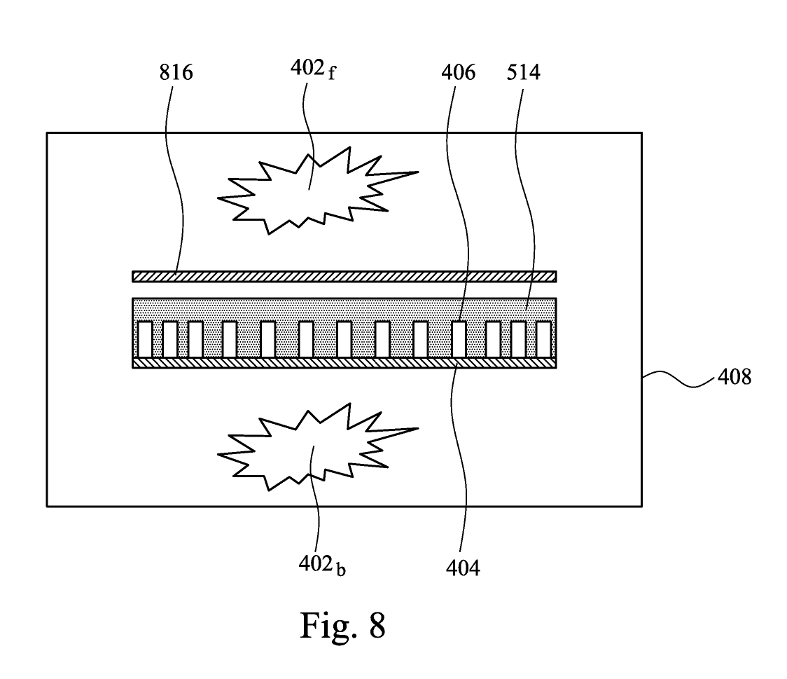

FIG. 8 illustrates yet another embodiment for an annealing process that is similar to the embodiment illustrated in FIG. 7, except that a low thermal mass heat shield 816 is added between the front-side heat source 402_{f} and the substrate 404. Under symmetric dual side heating the heat shield 816 and substrate 404 create an isothermal space in between them. Thus reflectivity variation induced by the layout of devices 406 will be reduced or eliminated because reflection energy is confined within the gap in between heat shield 816 and substrate 404. Because the variation in the amount of absorbed energy is reduced or eliminated, the substrate heats more evenly. The heat shield 816 may comprise, for example, a low thermal mass bulk silicon carbide SiC substrate having a thickness of about 100 μm to about 500 μm. The anneal process illustrated in FIG. 8 may be, for example, a RTA for a random variation on the mm scale or a systematic variation.

Thereafter, back-end-of-line processing may be performed. For example, an ILD layer may be formed, contacts may be formed through the ILD layer, IMD and metallization layers may be formed, interconnect structures may be formed, packaging and/or singulating may be formed, and/or the like.

In the foregoing specification, the invention has been described with reference to specific embodiments. However, various modifications and changes can be made by one skilled in the art without departing from the scope of the preferred embodiment. Accordingly, the specification and figures are to be regarded in an illustrative rather than a restrictive sense, and all such modifications are intended to be included within the scope of the preferred embodiment.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of making a semiconductor device, the method comprising:
providing a substrate having structures formed on a front side of the substrate and an anti-reflection (ARD) layer over the structures, the substrate having regions with implanted ions; and
annealing the substrate, a first heat source being located on a back side of the substrate.

2. The method of claim 1, wherein the annealing further includes a second heat source on the front side of the substrate.

3. The method of claim 2, further comprising placing a heat shield between the second heat source and the substrate.

4. The method of claim 1, wherein the annealing comprises one of a rapid thermal anneal.

5. The method of claim 1, wherein the ARD layer has a heat absorption coefficient of about 0.1.

6. The method of claim 1, wherein the ARD layer has a heat absorption coefficient of about 0.1 or higher.

7. The method of claim 1, wherein the ARD layer comprises amorphous carbon.

8. A method of making a semiconductor device, the method comprising:
providing a substrate having structures formed on a front side of the substrate, the substrate having regions with implanted ions; and
annealing the substrate using a backside heat source, the front side of the substrate being absent a direct heat source.

9. The method of claim 8, wherein the annealing comprises a rapid thermal anneal.

10. The method of claim 8, further comprising forming an anti-reflection deposition (ARD) over the structures on the front side of the substrate prior to the annealing.

11. A method of forming a semiconductor device, the method comprising:
performing a reflectivity scan of a die;
characterizing the reflectivity of the die as a systematic variation, a random variation on a first scale, or a random variation on a second scale;
performing a first anneal procedure if the die has been characterized as the systematic variation; and
performing a second anneal procedure if the die has been characterized as the random variation on the first scale, the first anneal procedure being different than the second anneal procedure.

12. The method of claim 11, further comprising performing the first anneal procedure if the die has been characterized as the random variation on the second scale.

13. The method of claim 11, wherein the reflectivity scan is performed at least in part using a Xeon light source.

14. The method of claim 11, wherein the performing the first anneal procedure comprises a rapid thermal anneal (RTA) such that a heat source is positioned on a backside of the die.

15. The method of claim 11, further comprising forming an anti-reflection dielectric (ARD) layer on a front side of the die.

16. The method of claim 15, wherein the performing the first anneal procedure comprises performing a rapid thermal anneal (RTA) such that a heat source is positioned on a front side of the die.

17. The method of claim 15, wherein the performing the first anneal procedure comprises performing rapid thermal anneal (RTA) such that a heat source is positioned on a front side of the die and on a backside of the die.

18. The method of claim 17, further comprising placing a heat shield between the heat source on the front side of the die.

19. The method of claim 11, wherein the performing the second anneal procedure comprises a millisecond anneal (MSA).

20. The method of claim 11, wherein the first scale is a sub-mm scale and the second scale is a mm scale.
